(19) United States
(12) Patent Application Publication
(10) Pub. No.: US 2010/0240214 A1
(43) Pub. Date: Sep. 23, 2010

(54) METHOD OF FORMING MULTI METAL LAYERS THIN FILM ON WAFER

(75) Inventors: YuShan Chiu, Taipei County (TW); Yi-Jen Lo, Taipei County (TW)

Correspondence Address: VOLPE AND KOENIG, P.C., UNITED PLAZA, 30 SOUTH 17TH STREET, PHILADELPHIA, PA, 19103, US

(73) Assignee: NANYA TECHNOLOGY CORP., Tao-Yuan Hsien (TW)

(21) Appl. No.: 12/501,125

(22) Filed: Jul. 10, 2009

(30) Foreign Application Priority Data
Mar. 20, 2009 (TW) 098109299

(51) Int. Cl. H01L 21/3205; C23C 16/44

(52) U.S. Cl. 438/656; 118/715; 257/E21.295

(57) ABSTRACT

A method of forming the multi metal layers thin film has Ti sputtered on top surface of a substrate by PVD first. Then, Ti is transformed into TiN via CVD. Thus, by skipping the extra process steps of wafer cleaning and surface treating, the method not only solves the stress problems between two different metal layers but also improves the cycle time and particle performance for the production without any yield impact.

### FIELD OF THE INVENTION

The present invention relates to a deposition process in the semiconductor field, and more particularly to a method for simplifying thin film deposition process.

### BACKGROUND OF THE INVENTION

In the semiconductor industry, for some characteristics of the material, thin film deposition becomes one of the most popular methods to deal with the material surface. Especially, the process is used for forming a layer of homogeneous or heterogeneous material film on the surface of a wafer.

A thin film on a wafer is generally manufactured through various processes, such as physical vapor deposition (PVD) or sputter deposition, chemical vapor deposition (CVD), cleaning (scrubber), anneal, as well as other specific multiple procedures to deal with the metal layer. Some chamber is usually configured as a single procedure in the overall manufacturing process, to deal with the wafer with the repeating deposition and the cleaning steps.

In a typical process, the wafer needs to be taken repeatedly in and out from the reaction chamber because of some special manufacturing procedures requirements, and different kinds of film layers need to be treated in different kinds of chambers and devices. Between each two steps, the surface of the film needs to be cleaned or directly deposited with another metal layer to clear the particles residues thereon. However, depositing another metal layer needs to be treated in different type of chamber.

Traditionally, a thin film is deposited by the metal organic chemical vapor deposition (MOCVD). When carrier gas passes through the metal organic precursor containers, it will lead the precursor saturated vapor to mix the other reaction gas in a reaction chamber, and then a chemical reaction happens on the top surface of the heated wafer to promote the deposition of the thin film. In general, the carrier gas is usually hydrogen, or nitrogen in some special cases.

Please refer to FIG. 1, which is the chemical structure diagram showing a conventional precursor, tetrakis-dimethyl amino titanium (TDMAT), of the metal organic chemical vapor deposition titanium nitride deposition. According to previous experiment result and some paper description, titanium reacts with tetrakis-dimethyl amino titanium during CVD TiN deposition, to form one kind of complex compound of titanium carbide (TiCx). This compound can be a contamination source to cause retention or bit line couple test loss after wafer burn-in (Backend test), therefore titanium nitride is essential before the metal organic chemical vapor deposition titanium nitride deposition if titanium is needed underneath at the silicon substance contacts. Unfortunately, if capping titanium nitride by physical vapor deposition sputter process directly, particle can be a problem because of stress difference between titanium and titanium nitride. Normally, titanium or titanium nitride will redeposit at sputter chamber side wall, due to stress difference, multiple layers are more unstable than a single layer, nevertheless doing pasting after a few wafers run, flaking happened at chamber side wall and target edge. Thus, a scrubber procedure is needed after the thin film deposition.

Please refer to FIG. 2, which is the profile diagram showing a conventional structure of the thin film deposition. The bottom substrate is a silicon wafer 20. The first titanium layer 21 is formed at the top surface of the silicon wafer 20 by physical vapor deposition sputtering procedure. Then, the first titanium nitride layer 22 is formed at the top surface of the first titanium layer 21 by physical vapor deposition sputtering procedure. Then, the second layer of titanium layer 23 is formed at the top surface of the first titanium nitride layer 22 by physical vapor deposition sputtering procedure. Then, scrubber procedure is needed to proceed. After the cleaning procedure, the process chamber having twice procedures of vacuuming and venting the vacuum processes, the wafer is also needed to be transferred to another chamber to finish the metal organic chemical vapor deposition and the plasma treatment to form the second titanium nitride layer 24, wherein the precursor of the metal organic chemical vapor deposition is tetrakis-dimethyl amino titanium. The plasma gas source used in plasma pre-treatment method is hydrogen and nitrogen (H2/N2).

Please refer to FIG. 3, which is the diagram showing a conventional thin film deposition process. First of all, a first titanium, a titanium nitride layer and a second titanium layer are formed respectively based on physical vapor deposition sputtering procedures. Then, the burdensome scrubber procedure is proceeded. All the procedures require considerable time and manpower. After the scrubber procedure, the plasma treatment process 33 is implemented with metal organic chemical vapor deposition titanium nitride layer deposition. Then, anneal procedure 34 is proceeded. Then, tungsten deposition procedure 35 is proceeded after anneal procedure 34.

Because of the physical vapor deposition of titanium or titanium nitride, the particles will be the problem. Therefore, implementing paste process after a few wafers run is necessary to prevent the particles flanking. Even so, the stress difference between titanium and titanium nitride is still the problem. The particles problem still exists. In conventional practice, the cleaning procedure is the only proper method to deal with the particles during the procedures. Furthermore, that the wafer needs to be transferred to another chamber in the cleaning process will also cause some negative effect to the product throughput and yield thereof.

To solve the above drawbacks in the prior art, the applicant uses a processing method for only depositing a titanium layer film on a wafer through a sputter chamber. Then, the applicant utilizes the chemical vapor deposition titanium nitride plasma to transform titanium into titanium nitride after physical vapor deposition titanium sputtering instead of capping titanium nitride directly. Thus, the current process flow is not only simplified (scrubber clean procedure omitted) but the particle issue is also solved.

### SUMMARY OF THE INVENTION

The main purpose of one of the present preferred embodiments provides a processing method for only depositing a titanium layer film on a wafer through a sputter chamber. Then, the chemical vapor deposition titanium nitride plasma is used to transform titanium into titanium nitride after physical vapor deposition titanium sputtering instead of capping titanium nitride directly. Thus, the current process flow is not only simplified but the particle issue is also solved. Furthermore, the present invention reduces the cycle time to increase the production capacity without any yield impact.

In accordance with one aspect of the preferred embodiments, a method for forming a thin film on a substrate is provided. The method includes steps of forming a titanium layer on the substrate, forming a first titanium nitride layer on the titanium layer via a first chemical vapor deposition, and directly forming a second titanium nitride layer on the first titanium nitride layer via a second chemical vapor deposition.

Preferably, the titanium layer is formed via a physical vapor deposition in a physical vapor deposition chamber, the first and the second chemical vapor depositions are performed in a chemical vapor deposition chamber, and the substrate is a semiconductor wafer.

Preferably, the titanium layer is formed by a sputtering process.

Preferably, the first titanium nitride layer is formed by a metal organic chemical vapor deposition plasma pretreatment.

Preferably, the plasma pretreatment uses a plasma gas source having a nitrogen-containing gas.

Preferably, the nitrogen-containing gas has a nitrogen.

Preferably, the second titanium nitride layer is directly formed on the first titanium nitride layer by a metal organic chemical vapor deposition plasma pretreatment and both the forming a first titanium nitride layer step and the directly forming step have a vacuum status kept unchanged.

Preferably, the plasma pretreatment uses a plasma gas source having a nitrogen/hydrogen-containing gas and a precursor.

Preferably, nitrogen/hydrogen-containing gas has a nitrogen and a hydrogen, and the precursor has a tetrakis-dimethyl amino titanium.

In accordance with another aspect of the present invention, a method for forming a thin film is provided. The methods includes steps of providing a substrate in a reaction chamber, providing a first plasma gas source to the reaction chamber and forming a first layer on the substrate by a first chemical vapor deposition, and providing a second plasma gas source to the reaction chamber and directly forming a second layer on the first layer by a second chemical vapor deposition.

Preferably, the substrate is a semiconductor wafer having a titanium layer formed thereon via a physical vapor deposition, and the first layer is formed on the titanium layer.

Preferably, the first and the second layers are titanium nitride layers.

Preferably, the thin film has multiple metal layers, the substrate is a semiconductor wafer and the reaction chamber is a chemical deposition reaction chamber.

Preferably, the first and the second chemical vapor depositions are performed via plasma pretreatments, the first plasma gas has a nitrogen and the second plasma gas has a nitrogen, a hydrogen and a precursor.

Preferably, the precursor has a tetrakis-dimethyl amino titanium.

Preferably, the step of directly forming the second layer on the first layer is free from a vacuum vent in the process chamber.

In accordance with a further aspect of the preferred embodiments, a thin-film forming device for a substrate is provided. The thin-film forming device includes a titanium layer forming device forming a titanium layer on the substrate; and a first and a second titanium nitride layers forming device forming a first titanium nitride layer on the titanium layer and directly forming a second titanium nitride layer on the first titanium nitride layer.

Preferably, the titanium layer forming device is a physical deposition reaction chamber, the substrate is a wafer, the titanium layer is formed on the wafer by a physical vapor deposition, the first and the second titanium nitride layers forming device is a chemical deposition reaction chamber, the first titanium nitride layer is formed on the titanium layer by a first chemical vapor deposition, the second titanium nitride layer is directly formed on the first titanium nitride layer by a second chemical vapor deposition, and the physical and the chemical deposition reaction chambers are configured in a wafer processing system.

The above objects of the present invention will become more readily apparent to those ordinarily skilled in the art after reviewing the following detailed descriptions and accompanying drawings, in which:

### BRIEF DESCRIPTION OF THE DRAWINGS

FIG. 1 is the chemical structure diagram showing a conventional precursor, tetrakis-dimethyl amino titanium (TDMAT), of the metal organic chemical vapor deposition titanium nitride deposition.

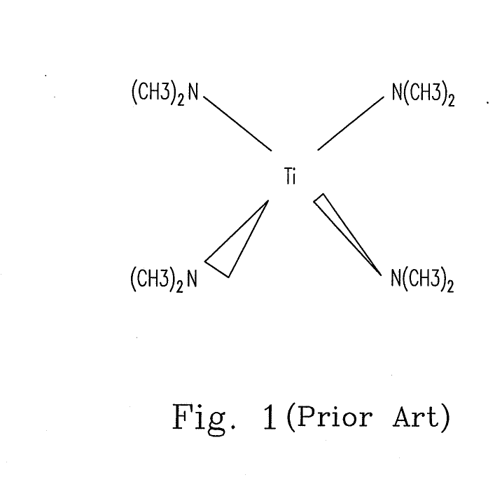

FIG. 2 is the profile diagram showing a conventional structure of the thin film deposition.

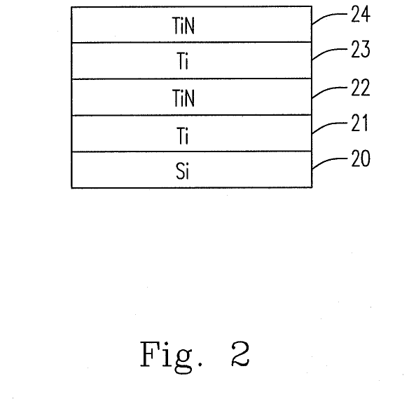

FIG. 3 is the diagram showing a conventional thin film deposition process.

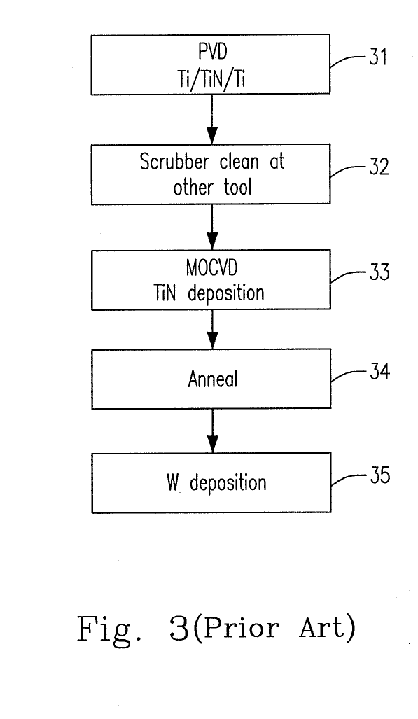

FIG. 4 is the profile diagram showing the present structure of the thin film deposition.

FIG. 5 is the diagram showing the present thin film deposition process.

FIG. 6(a) is a typical diagram showing the yield test distribution of the present invention, FIG. 6(b) is a typical table showing the permanent yield test of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

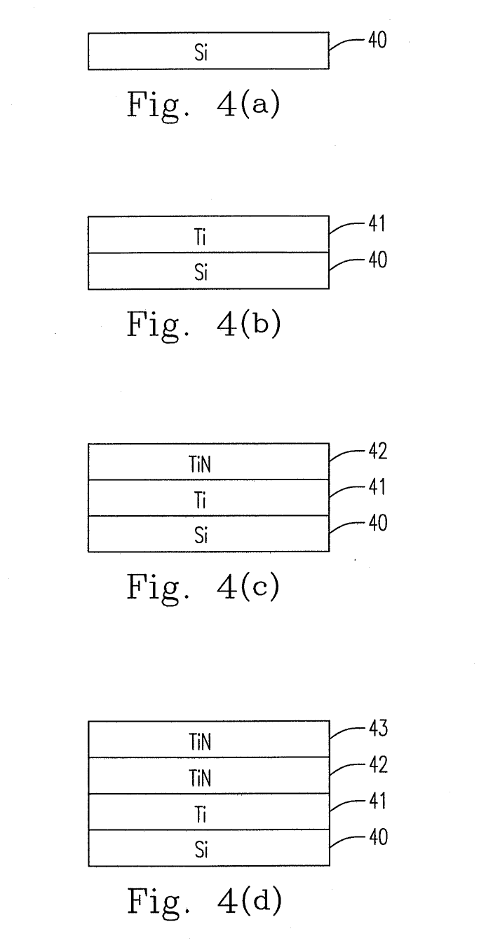

Please refer to FIG. 4, which is the profile diagram showing the present structure of the thin film deposition. The following FIGS. 4(a)˜(d) are used to illustrate the forming method for the thin film deposition of the present invention. In FIG. 4(a), a semiconductor wafer is firstly provided, wherein the semiconductor is a silicon wafer 40.

Please refer to FIG. 4(b), a titanium layer 41 is formed on the top surface of the silicon wafer 40 by physical vapor deposition sputtering method.

Please refer to FIG. 4(c), according to FIG. 4(b), a titanium nitride layer 42 is formed on the top surface of the titanium layer 41 by using a plasma pre-treatment procedure of metal organic chemical vapor deposition method. The plasma pre-treatment procedure is implemented in a chamber containing nitrogen. That is, plasma gas source used in the plasma pre-treatment procedure is nitrogen.

Please refer to FIG. 4(d), according to FIG. 4(c), tetrakis-dimethyl amino titanium, a precursor of metal organic chemical vapor deposition is used for plasma pretreatment on the titanium nitride layer 42 to remove carbide impurities therein. A titanium nitride layer 43 is formed on the top surface of the titanium nitride layer 42. The plasma pre-treatment is proceeded in a pressure chamber containing nitrogen and hydrogen. Thus, the plasma gas source used in plasma pre-treatment method is hydrogen and nitrogen. Therefore, the titanium nitride film is formed with a good step coverage and uniformity.

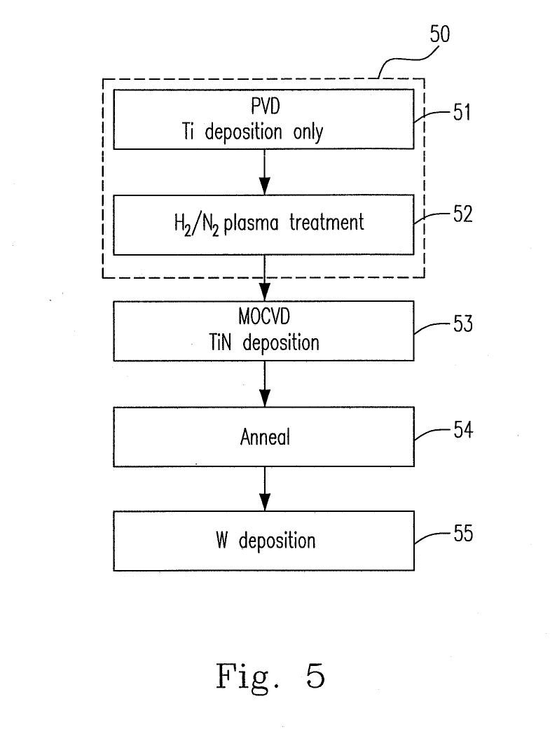

Please refer to FIG. 5, which is the diagram showing the present thin film deposition process. The scrubber procedure is eliminated after the procedure that a titanium layer 51 is formed by a physical vapor deposition to cover the silicon wafer. Then, a titanium nitride layer 52 is formed at the top of the titanium layer 51 by metal organic chemical vapor deposition plasma pre-treatment procedure at the same chamber platform. Then, another titanium nitride layer 53 is also formed by the same plasma pre-treatment procedure, but using the different gas source at the same chamber platform. Then, an anneal procedure 54 is proceeded. Then, a tungsten deposition procedure 55 is proceeded after the anneal procedure 54.

Based on the above description and showings of FIG. 5, the simplified flowing processes in block 50 show the biggest differences between the present preferred embodiments and the conventional technique. The present preferred embodiments moves the wafer to the metal deposition reaction chamber at the same processing platform without moving the wafer over and over again out of the vacuum processing environment to deposit a metal film on the top of the metal film silicon wafer. Because the metal film surface silicon wafer is immediately transferred to the metal deposition reaction chamber, and maintaining in the same vacuum environment of the wafer processing system, the particles and the contaminants can not be diffused on the surface of the metal film.

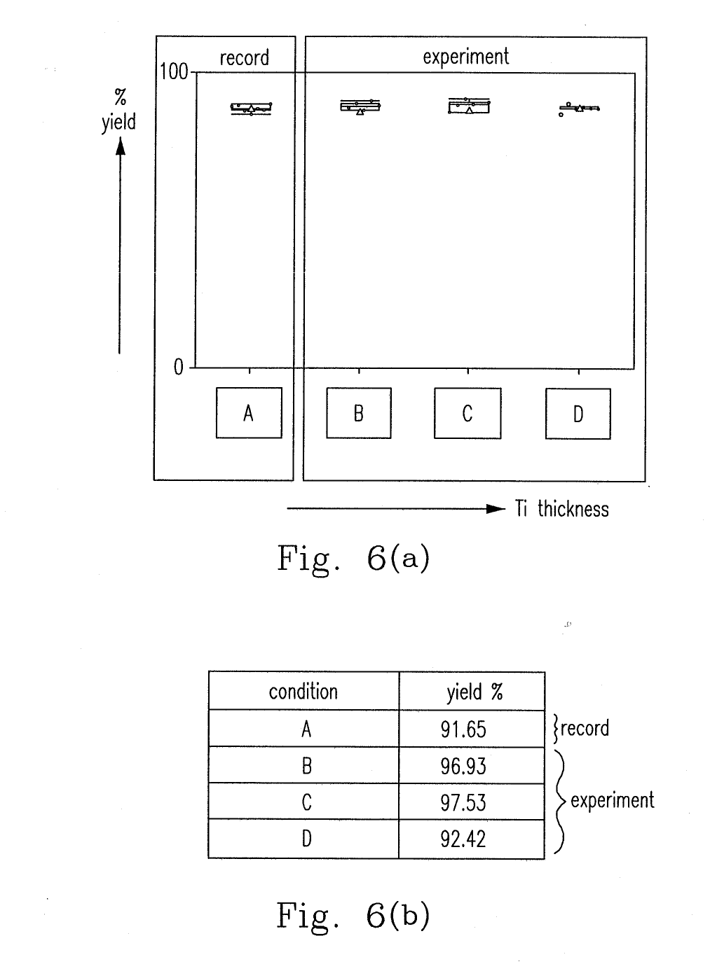

Please refer to FIG. 6(a), which is a typical diagram showing the yield test distribution of the present preferred embodiments, wherein the horizontal axis shows the different thickness of the titanium. The small blocks in figure are divided into four conditions A, B, C and D to perform a permanent test, wherein A is the record group, B, C and D are the experimental group. Vertical axis shows the yields of the A, B, C and D with different thickness of the titanium by the results of trial, and the average placement values are shown in the quadrant coordinates. FIG. 6(b) is a typical table showing the permanent yield test of the present preferred embodiment. The test results from the record group and experimental group show that the yields are not affected.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for forming a thin film on a substrate, comprising the steps of:
forming a titanium layer on the substrate;
forming a first titanium nitride layer on the titanium layer via a first chemical vapor deposition; and
directly forming a second titanium nitride layer on the first titanium nitride layer via a second chemical vapor deposition.

2. The method according to claim 1, wherein the titanium layer is formed via a physical vapor deposition in a physical vapor deposition chamber, the first and the second chemical vapor depositions are performed in a chemical vapor deposition chamber, and the substrate is a semiconductor wafer.

3. The method according to claim 1, wherein the titanium layer is formed by a sputtering process.

4. The method according to claim 1, wherein the first titanium nitride layer is formed by a metal organic chemical vapor deposition plasma pretreatment.

5. The method according to claim 4, wherein the plasma pretreatment uses a plasma gas source having a nitrogen-containing gas.

6. The method according to claim 5, wherein the nitrogen-containing gas has a nitrogen.

7. The method according to claim 1, wherein the second titanium nitride layer is directly formed on the first titanium nitride layer by a metal organic chemical vapor deposition plasma pretreatment and both the forming a first titanium nitride layer step and the directly forming step have a vacuum status kept unchanged.

8. The method according to claim 7, wherein the plasma pretreatment uses a plasma gas source having a nitrogen/hydrogen-containing gas and a precursor.

9. The method according to claim 8, wherein the nitrogen/hydrogen-containing gas has a nitrogen and a hydrogen, and the precursor has a tetrakis-dimethyl amino titanium.

10. A method for forming a thin film, comprising the steps of:
providing a substrate in a reaction chamber;
providing a first plasma gas source to the reaction chamber and forming a first layer on the substrate by a first chemical vapor deposition; and
providing a second plasma gas source to the reaction chamber and directly forming a second layer on the first layer by a second chemical vapor deposition.

11. The method according to claim 10, wherein the substrate is a semiconductor wafer having a titanium layer formed thereon via a physical vapor deposition, and the first layer is formed on the titanium layer.

12. The method according to claim 11, wherein the first and the second layers are titanium nitride layers.

13. The method according to claim 10, wherein the first and the second layers are titanium nitride layers.

14. The method according to claim 10, wherein the thin film has multiple metal layers, the substrate is a semiconductor wafer and the reaction chamber is a chemical deposition reaction chamber.

15. The method according to claim 10, wherein the first and the second chemical vapor depositions are performed via plasma pretreatments, the first plasma gas has a nitrogen and the second plasma gas has a nitrogen, a hydrogen and a precursor.

16. The method according to claim 15, wherein the precursor has a tetrakis-dimethyl amino titanium.

17. The method according to claim 10, wherein the step of directly forming the second layer on the first layer is free from a vacuum vent in the process chamber.

18. A thin-film forming device for a substrate, comprising:
a titanium layer forming device forming a titanium layer on the substrate; and
a first and a second titanium nitride layers forming device forming a first titanium nitride layer on the titanium layer and directly forming a second titanium nitride layer on the first titanium nitride layer.

19. The device according to claim 18, wherein the titanium layer forming device is a physical deposition reaction chamber, the substrate is a wafer, the titanium layer is formed on the wafer by a physical vapor deposition, the first and the second titanium nitride layers forming device is a chemical deposition reaction chamber, the first titanium nitride layer is formed on the titanium layer by a first chemical vapor deposition, the second titanium nitride layer is directly formed on the first titanium nitride layer by a second chemical vapor deposition, and the physical and the chemical deposition reaction chambers are configured in a wafer processing system.
